(19) United States
(12) Patent Application Publication
(10) Pub. No.: US 2011/0104365 A1
(43) Pub. Date: May 5, 2011

(54) Method for Sealing Edge Portion of Double-Layered Product and Apparatus for Sealing Edge Portion of Double-Layered Product

(75) Inventors: Shoji Hidaka, Osaka-shi (JP); Masaki Mita, Osaka-shi (JP); Seiki Tarumi, Osaka-shi (JP)

(73) Assignee: Sun Tool Corporation, Osaka-shi, Osaka-fu (JP)

(21) Appl. No.: 13/002,031

(22) PCT Filed: Feb. 18, 2010
(86) PCT No.: PCT/JP2010/052914

§ 371 Date: Dec. 29, 2010

(30) Foreign Application Priority Data
Feb. 20, 2009 (JP) 2009-037860
Mar. 10, 2009 (JP) 2009-056066

(51) Int. Cl. B05D 5/12

(52) U.S. Cl. 427/74; 427/427.3; 118/323

(57) ABSTRACT

An object of the present invention to make a measure against moisture entry into an edge portion of a double-layered product such as a photovoltaic cell panel or an electronic panel more reliable. A tip end of the coating agent discharge port is arranged to face a part of an edge portion of a double-layered product serving as the work to be coated. An applying nozzle having the slit-shaped coating agent discharge is rotated and driven to allow a direction of the slit-shaped coating agent discharge port changeable as viewed in a planar state.

### TECHNICAL FIELD

The present invention relates to a photovoltaic cell panel for photovoltaic generation and an electronic panel (a liquid crystal plate, an organic EL plate) for TV image display or PR image display (an electronic advertising display plate).

More specifically, a photovoltaic cell panel or an electronic panel of this kind is a double-layered plate product formed by sandwiching a light receiving element plate or a light emitting element plate between double plates. The present invention relates to a method for applying a sealing agent to an edge portion of the double-layered plate product and a sealing structure at the edge portion of the double-layered plate product.

### BACKGROUND ART

As a known technique of a measure against moisture entry into a mating surface of a double-layered plate product such as a photovoltaic cell panel, Japanese Unexamined Patent Publication No. 2003-103214, “Method for Applying Sealing Agent,” exists.

In the above known technique, a level portion is formed at an edge portion of two flat plates, and a sealing agent is applied to the level portion by a nozzle of an applying unit. In the sealing structure at the edge portion of the known double-layered plate product, the sealing agent is dropped and applied only to the level portion in a bead state, and thus there is a problem in which a measure against moisture entry into the mating surface is not reliable.

### DISCLOSURE OF THE INVENTION

In a photovoltaic cell panel or an electronic panel, since a light receiving element plate or a light emitting element plate is an electronic product, moisture needs to be prevented from entering. Also, when the photovoltaic cell panel or the electronic panel is installed outside, it is highly possible that rainwater may enter therein.

It is therefore an object of the present invention to make a measure against moisture entry into an edge portion of a double-layered product such as a photovoltaic cell panel or an electronic panel more reliable.

It is another object of the present invention to improve efficiency of a sealing operation of the edge portion of the double-layered product.

The invention according to Claim 1 provides a method for sealing an edge portion of a double-layered product, the method including the steps of discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port, wherein a hot-melt adhesive is used as the sealing coating agent, a tip end of the coating agent discharge port is arranged to face at least two surfaces (an edge surface and an upper surface) of an edge portion of a double-layered product serving as the work to be coated, and a thickness of an applied coating agent M at a part parallel to an upper surface of a work W to be coated is changeably set by setting of a distance between the tip end of the coating agent discharge port and the upper surface of the work to be coated.

The invention according to Claim 2 provides a method for sealing an edge portion of a double-layered product, the method including the steps of: discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port, wherein a hot-melt adhesive is used as the sealing coating agent, the coating agent discharge port is arranged to face at least three surfaces (an edge surface, an upper surface and a lower surface) out of circumferential surfaces at an edge portion of a double-layered product so as to discharge the sealing coating agent to the three surfaces (the edge surface, the upper surface and the lower surface) at the edge portion of the double-layered product, a thickness of an applied coating agent M at a part parallel to an upper surface of a work W to be coated is changeable by setting of a distance between a tip end of the coating agent discharge port and the upper surface of the work to be coated, and a thickness of the applied coating agent M at a part parallel to a lower surface of the work W to be coated is changeable by setting of a distance between the tip end of the coating agent discharge port and the lower surface of the work to be coated.

The invention according to Claim 3 provides a method for sealing an edge portion of a double-layered product, the method including the steps of: discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port, wherein a hot-melt adhesive is used as the sealing coating agent, the coating agent discharge port is arranged to face at least three surfaces (an edge surface, an upper surface and a lower surface) out of circumferential surfaces at an edge portion of a double-layered product so as to discharge the sealing coating agent to the three surfaces (the edge surface, the upper surface and the lower surface) at the edge portion of the double-layered product, a thickness of an applied coating agent M at a part parallel to an upper surface of a work W to be coated is changeable by setting of a distance between a tip end of the coating agent discharge port and the upper surface of the work to be coated, a thickness of the applied coating agent M at a part parallel to a lower surface of the work W to be coated is changeable by setting of a distance between the tip end of the coating agent discharge port and the lower surface of the work to be coated, and a thickness of the applied coating agent M at an edge of the edge portion of the work W to be coated is changeable by setting of a distance between the tip end of the coating agent discharge port and an edge of the work to be coated.

The invention according to Claim 4 provides a method for sealing an edge portion of a double-layered product, the method including the steps of: discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port, wherein a hot-melt adhesive is used as the sealing coating agent, the coating agent discharge port is arranged to face at least three surfaces (an edge surface, an upper surface and a lower surface) out of circumferential surfaces at an edge portion of a double-layered product so as to discharge the sealing coating agent to the three surfaces (the edge surface, the upper surface and the lower surface) at the edge portion of the double-layered product, a thickness of an applied coating agent M at a part parallel to an upper surface of a work W to be coated is changeable by setting of a distance between a tip end of the coating agent discharge port and the upper surface of the work to be coated, a thickness of the applied coating agent M at a part parallel to a lower surface of the work W to be coated is changeable by setting of a distance between the tip end of the coating agent discharge port and the lower surface of the work to be coated, and the gun unit is made to be supported by gun unit driving means via a vertical positional adjusting mechanism so that the distance between the tip end of the coating agent discharge port and the upper surface of the work to be coated may be changeable by operation of the vertical positional adjusting mechanism to obtain a desired value for the thickness of the applied coating agent M.

The invention according to Claim 5 provides a method for sealing an edge portion of a double-layered product, the method including the steps of: discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port, wherein a hot-melt adhesive is used as the sealing coating agent, the coating agent discharge port is arranged to face at least three surfaces (an edge surface, an upper surface and a lower surface) at an edge portion of a double-layered product so as to discharge the sealing coating agent to the three surfaces (the edge surface, the upper surface and the lower surface) at the edge portion of the double-layered product, the gun unit is made to be supported by gun unit driving means via a vertical positional adjusting mechanism so that a distance between a tip end of the coating agent discharge port and the upper surface of the work to be coated and a distance between the tip end of the coating agent discharge port and the lower surface of the work to be coated may be changeable by operation of the vertical positional adjusting mechanism to obtain a desired value for the thickness of the applied coating agent M.

In the invention according to Claim 6, in accordance with the above invention, a plurality of applying nozzles having different vertical distances of laterally-facing application spaces are provided and selectively used to adjust a space against the work to be coated and obtain a desired value for the thickness of the applied coating agent M.

In the invention according to Claim 7, in accordance with the above invention, a rubber-based hot-melt adhesive (hot butyl) is used as the hot-melt adhesive serving as the sealing coating agent, and the gun unit with heating means is provided to so as to allow the rubber-based hot-melt adhesive (hot butyl) supplied to the applying nozzle in a molten state is discharged in a liquid state from the tip end of the coating agent discharge port, and in a state where the rubber-based hot-melt adhesive (hot butyl) M has been applied on the coating surface of the work to be coated, the rubber-based hot-melt adhesive (hot butyl) M is cooled and is changed into a solid state, thereby changing the rubber-based hot-melt adhesive (hot butyl) M applied to the work to be coated into a solid state.

The invention according to Claim 10 provides an apparatus for sealing an edge portion of a double-layered product, the apparatus for discharging a sealing coating agent supplied from an applying unit main body from a coating agent discharge port formed at an applying nozzle at a tip end portion of a gun unit, and applying the sealing coating agent to a coating surface of a work to be coated facing the coating agent discharge port, wherein a tip end of the coating agent discharge port is formed in a slit shape facing a part of a vertical cross-sectional circumferential surface shape of the edge portion of the double-layered product serving as the work to be coated.

The invention according to Claim 14 provides an apparatus for sealing an edge portion of a double-layered product, wherein the applying nozzle having the slit-shaped coating agent discharge port of the invention according to Claim 10 is different each other to allow a direction of the slit-shaped coating agent discharge port changeable as viewed in a planar state.

The invention according to Claim 15 provides an apparatus for sealing an edge portion of a double-layered product, wherein the gun unit having a plurality of applying nozzles in which the direction of the slit-shaped coating agent discharge port of the invention according to Claim 10 is different each other, to allow a direction of the slit-shaped coating agent discharge port changeable as viewed in a planar state.

The invention according to Claim 18 provides an apparatus for sealing an edge portion of a double-layered product wherein, in addition to the invention according to Claim 10, the double-layered product is structured to sandwich a flexible light receiving element plate or a light emitting element plate between upper and lower plates made of flexible plastic sheets.

The present invention exerts an effect of reliable and strong sealing of an edge portion of a double-layered product by forming a coating agent in a predetermined shape (thickness, application range, cross-sectional shape, and the like) on at least two surfaces (an edge surface and an upper surface) of the edge portion of the double-layered product and forming a coating surface of the sealing coating agent by applying a pressure force toward a work to be coated.

The application thickness of the sealing coating agent to the work to be coated can be a predetermined application thickness and can be changed to a desired value as needed.

Since a silicon-based adhesive conventionally applied as a sealing coating agent is cured by reaction with moisture, the sealing coating agent is in an uncured and soft state immediately after being applied to the work to be coated, which makes it impossible to proceed to the subsequent process continuously. However, a hot-melt adhesive used as the sealing coating agent comes to a solid state immediately after being applied since the hot-melt adhesive is cured by reaction with heat, which makes it possible to easily proceed to the subsequent process (conveyance to another work area, attachment of a protection material such as an aluminum frame, or the like).

Especially, in a case where a rubber-based hot-melt adhesive (hot butyl) is applied, in a state of being applied to the work to be coated, the adhesive is changed from a molten (liquid) state to a solid state due to rapid temperature change caused by output from the heated applying nozzle, which makes it possible to proceed to the subsequent process in a continuous manner more easily.

The invention according to Claim 10 exerts an effect in which setting the shape of the slit-shaped coating agent discharge port as needed enables arbitrary setting of the shape (including the application range and application thickness) of the sealing structure at the edge portion of the double-layered product, and in which, by bringing the coating agent into pressure contact with the circumferential surface of the work to be coated while the applying nozzle is moved relative to the work to be coated, the coating agent applied to the work to be coated can be formed in a predetermined shape (thickness, application range, cross-sectional shape, and the like).

The invention according to Claim 14 exerts an effect in which, since rotating and driving the applying nozzle allow a direction of the slit-shaped coating agent discharge port that is the invention according to Claim 10 changeable as viewed in a planar state, a continuous unicursal sealing agent applying operation can be performed on all edges of the edge portion of the double-layered product (e.g., the whole circumferential surface of a rectangular photovoltaic cell panel). Accordingly, operation efficiency can be improved.

The invention according to Claim 15 exerts an effect in which, by allowing a direction of the slit-shaped coating agent discharge port changeable as viewed in a planar state by selectively operating a plurality of applying nozzles and by changing a relative position of the gun unit to each edge of the edge portion of the double-layered product, a continuous sealing agent applying operation can be performed on all edges of the edge portion of the double-layered product (e.g., the whole circumferential surface of a rectangular photovoltaic cell panel). Accordingly, the operation efficiency can be improved.

The invention according to Claim 18 exerts an effect of enabling the double-layered product to be attached and installed on a curved surface or a wall surface of a building by making the double-layered product flexible.

### BRIEF DESCRIPTION OF THE DRAWINGS

FIG. 1 is a vertical cross-sectional view schematically showing an applying unit equipped with an apparatus for sealing an edge portion of a double-layered product according to the present invention.

FIGS. 2(a) to 2(c) are explanatory views each showing a coating agent discharge port, which is a main part of the present invention.

FIGS. 3(a) to 3(d) are explanatory views each showing an applying nozzle.

FIGS. 4(a) to 4(d) are vertical cross-sectional views each showing an applying head.

FIGS. 5(a) to 5(c) are explanatory views each showing an application state to a work to be coated.

FIGS. 6(a) and 6(b) show an applying unit, which is an embodiment of the invention according to Claim 14; where FIG. 6(a) is a cross-sectional view, and FIG. 6(b) is an explanatory view describing an application state.

FIG. 7 is an explanatory view showing an application operation of the applying unit.

FIG. 8 is a vertical cross-sectional view of an applying unit, which is an embodiment of the invention according to Claim 15.

FIG. 9 is a schematic view showing an arrangement of four applying nozzles.

FIG. 10 is an explanatory view showing an application operation of the applying unit.

FIGS. 11(a) to 11(e) schematically show a horizontal moving mechanism of a gun unit; where FIG. 11(a) is a plan view, FIG. 11(b) is a front view, and FIG. 11(c) is a partially cross-sectional, partial left side view.

FIGS. 12(a) and 12(b) schematically show a vertical moving mechanism of a gun unit; where FIG. 12(a) is a partially cross-sectional, partial right side view, and FIG. 12(b) is a front view.

FIGS. 13(a) and 13(b) are explanatory views showing change in a distance d1 between a tip end of the coating agent discharge port and an upper surface of a work to be coated; where FIG. 13(a) shows a state before change, and FIG. 13(b) shows an example of change by raise of a gun unit.

FIGS. 14(a) to 14(c) are explanatory views showing change in the distance d1 between the tip end of the coating agent discharge port and the upper surface of the work to be coated and a distance d2 between the tip end of the coating agent discharge port and a lower surface; where FIG. 14(a) shows a state before change, FIG. 14(b) shows an example of change by replacement of an applying head and raise of a gun unit, and FIG. 14(c) shows an example of change only by the raise of the gun unit.

FIGS. 15(a) and 15(b) are explanatory views showing change in a distance d3 between the tip end of the coating agent discharge port and the edge of the work to be coated; where FIG. 15(a) shows a state before change, and FIG. 15(b) shows an example of change by horizontal movement of the gun unit.

FIGS. 16(a) and 16(b) show a double-layered product formed in a flat plate shape to which the present invention has been applied; where FIG. 16(a) is a perspective view, and FIG. 16(b) is a cross-sectional view.

FIGS. 17(a) and 17(b) show a double-layered product formed in a curved plate shape to which the present invention has been applied; where FIG. 17(a) is a perspective view, and FIG. 17(b) is a cross-sectional view.

### BEST MODE FOR CARRYING OUT THE INVENTION

Hereinafter, a method for sealing an edge portion of a double-layered product and an apparatus for sealing the edge portion of the double-layered product according to the present invention will be described in detail based on an embodiment practiced by applying the present invention to a sealing structure at an edge portion of a photovoltaic cell panel.

As a sealing coating agent, a rubber-based hot-melt adhesive (hot butyl) is used.

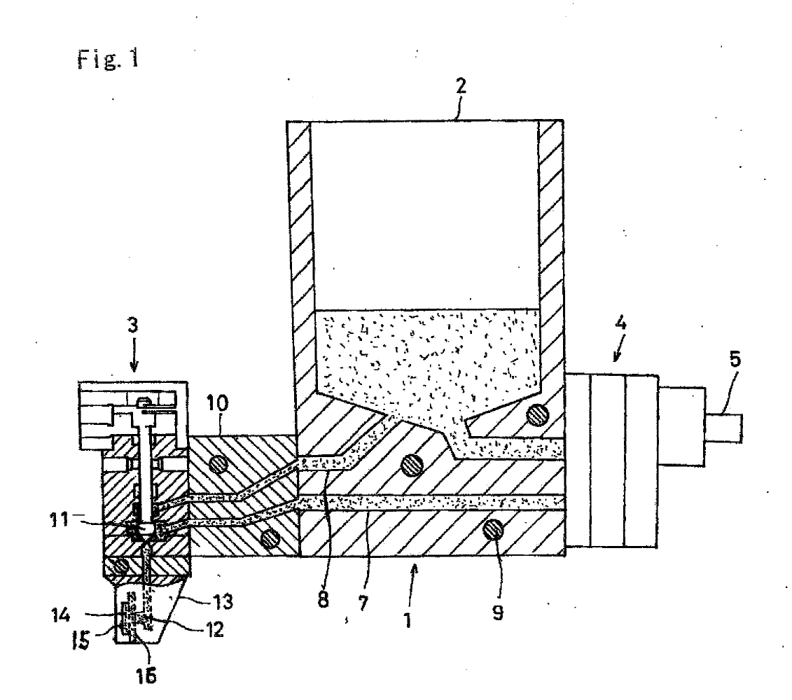

Referring to FIG. 1, an applying unit 1 is equipped with a gun unit 3 on one side of a main body block 2 and a gear pump 4 and a servo motor 5 on the other side, wherein a molten tank 6 is formed at the upper part of the main body block 2, and a connection block 10 is disposed between the gun unit 3 and the main body block 2.

In the main body block 2, a supply circuit 7 and a return circuit 8 are formed, and a heating member 9 is internally installed to keep the main body block 2 at a predetermined high temperature. Therefore, a rubber-based hot-melt adhesive (hot butyl) M supplied in the supply circuit 7 of the main body block 2 is in a melt, liquid state.

In the gun unit 3, a valve mechanism 11 is internally installed so as to control supply of the rubber-based hot-melt adhesive (hot butyl) to a supply path 12 at an applying head 13 at a lower portion of the gun unit 3.

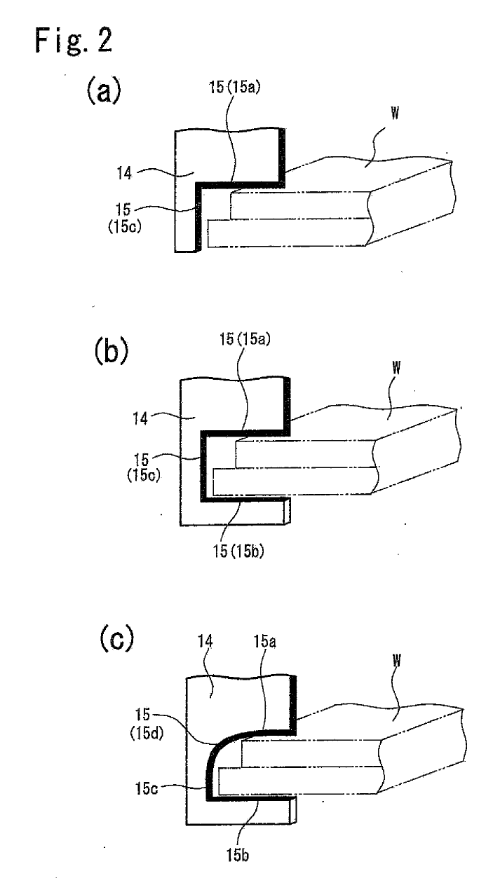

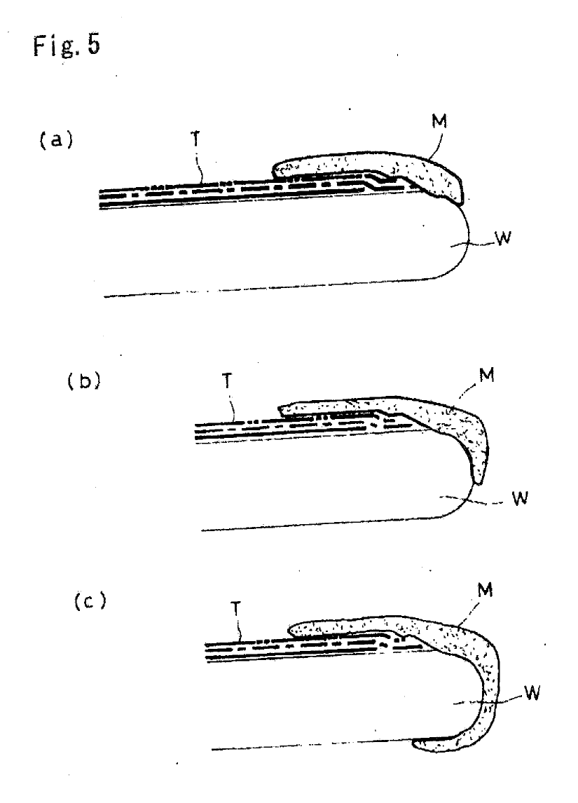

The applying nozzle 13 at the lower portion of the gun unit 3 is equipped with a coating agent discharge port 14 formed in a slit shape, whose tip end 15 is formed in each shape shown in FIGS. 2(a) to 2(c) so as to be formed and applied in an application state shown in FIGS. 5(a) to 5(c). In FIGS. 5(a) to 5(c), T denotes a back sheet for surface protection of a double-layered product.

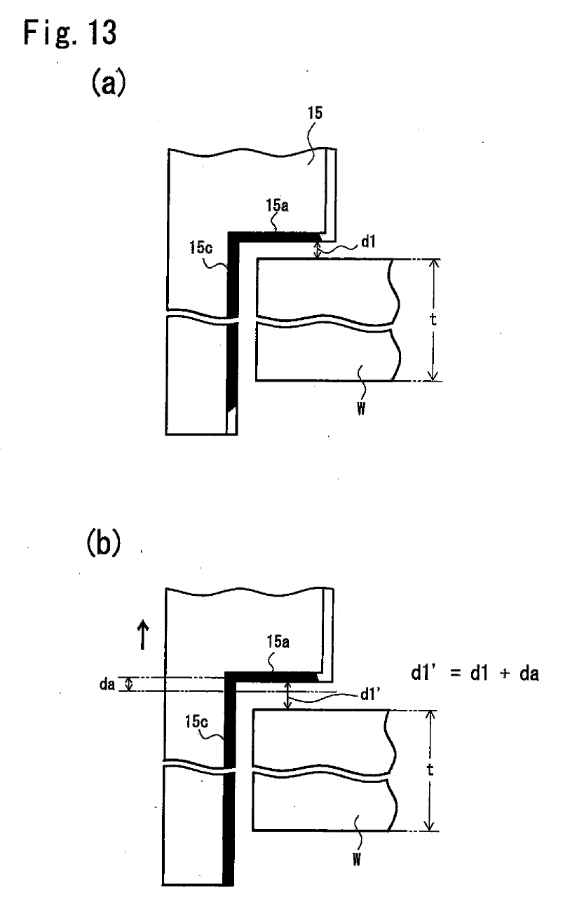

In FIGS. 5(a) to 5(c), the thickness of the applied coating agent M at a part parallel to an upper surface of a work W to be coated is 0.3 mm to 2 mm. Referring to FIGS. 13, 14 and 15, the thickness of the work W to be coated is kept to be a setting value determined based on a distance d1 on the upper side on the upper surface of the work W to be coated, a distance d2 on the lower side on the lower surface of the work W to be coated, a distance d3 on the lateral side on the edge surface of the work W to be coated, and the like.

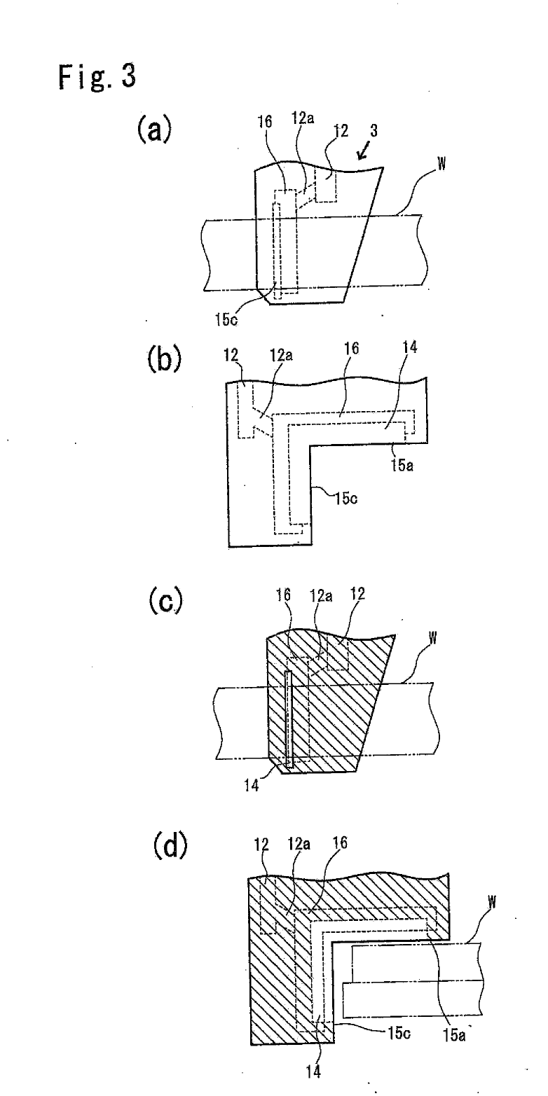

FIGS. 3(a) to 3(d) show the applying nozzle 13 equipped with the coating agent discharge port 14 shown in FIG. 2(a), where FIG. 3(a) is a front view, FIG. 3(b) is a side view, FIG. 3(c) is a vertical cross-sectional view seen from the front showing a tip end vertical portion 15c of the coating agent discharge port 14, and FIG. 3(d) is a vertical cross-sectional view of the side view showing the tip end vertical portion 15c and a tip end horizontal portion 15a of the coating agent discharge port 14.

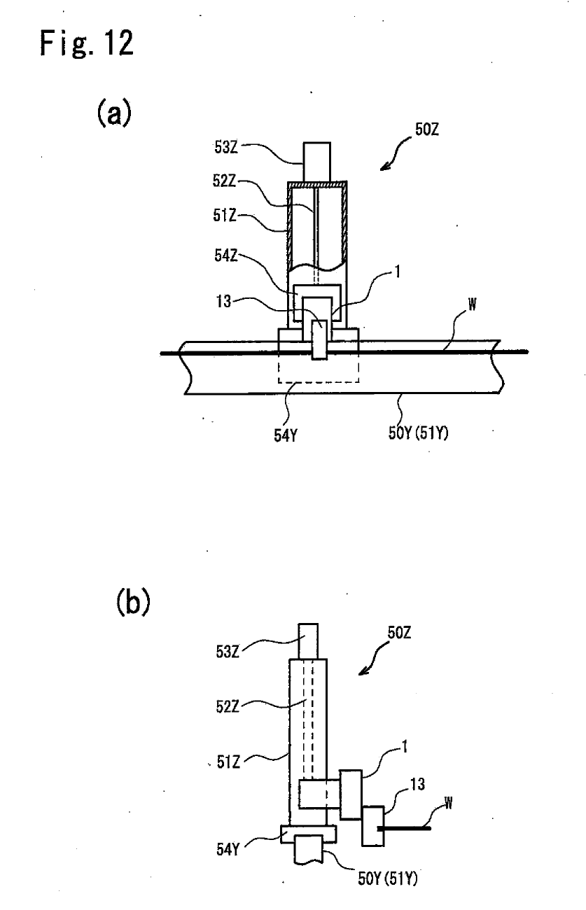

In FIGS. 3(a) to 3(d), 12 denotes the supply path, and 16 denotes a coating agent chamber that communicates into the supply path 12 via a communication path 12a and communicates into the slit-shaped coating agent discharge port 14. The coating agent is supplied from the supply path 12 to the coating agent discharge port 14 via the communication path 12a and the coating agent chamber 16, and the coating agent is then applied to the edge surface and the upper surface of the work W to be coated from the tip end vertical portion 15c and the tip end horizontal portion 15a.

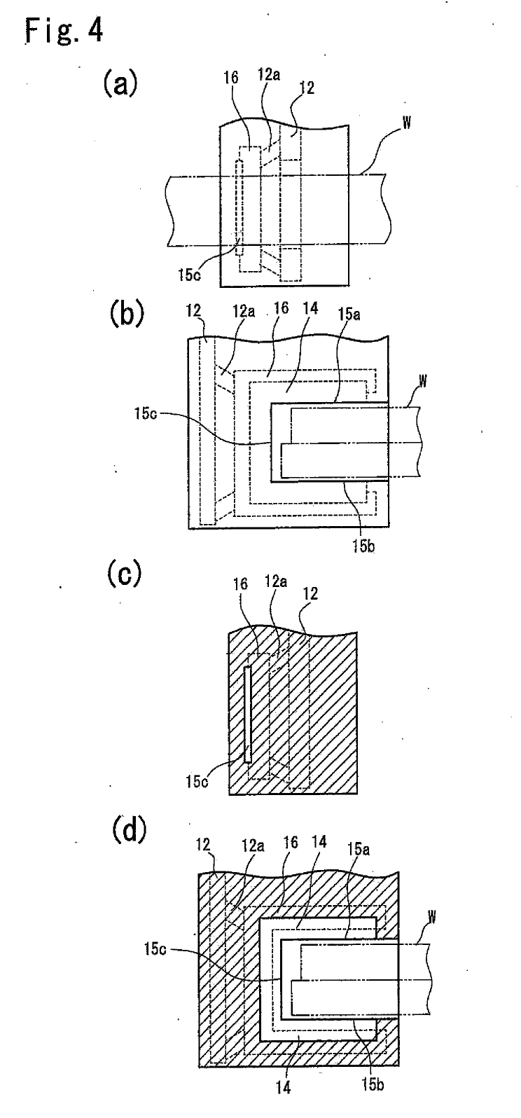

FIGS. 4(a) to 4(d) show the applying nozzle 13 equipped with the coating agent discharge port 14 shown in FIG. 2(b), where FIG. 4(a) is a front view, FIG. 4(b) is a side view, FIG. 4(c) is a vertical cross-sectional view seen from the front showing a tip end vertical portion 15c of the coating agent discharge port 14, and FIG. 4(d) is a vertical cross-sectional view of the side view showing the tip end vertical portion 15c, the tip end horizontal portion 15a and a tip end horizontal portion 15b of the coating agent discharge port 14.

In FIGS. 4(a) to 4(d), similar to FIGS. 3(a) to 3(d), the coating agent is supplied from the supply path 12 to the coating agent discharge port 14 via the communication path 12a and the coating agent chamber 16, and the coating agent is then applied to the upper surface, the edge surface and the lower surface of the work to be coated from the tip end vertical portion 15c, the tip end horizontal portion 15a and the tip end second horizontal portion 15b.

FIGS. 5(a) to 5(c) show application states of the rubber-based hot-melt adhesive (hot butyl) M, and the coating agent is brought into pressure contact with the circumferential surface of the work to be coated while the applying nozzle is moved relative to the work to be coated to form the coating agent applied to the work to be coated in a predetermined shape (thickness, application range, cross-sectional shape, and the like).

FIG. 5(a) shows an example of applying the rubber-based hot-melt adhesive (hot butyl) M to the upper surface of the work W to be coated by the tip end horizontal portion 15a.

FIG. 5(b) shows an example of applying the rubber-based hot-melt adhesive (hot butyl) M to the upper surface and the edge surface of the work to be coated by the tip end vertical portion 15c and the tip end horizontal portion 15a.

FIG. 5(c) shows an example of applying the rubber-based hot-melt adhesive (hot butyl) M to the upper surface, the edge surface and the lower surface of the work to be coated by the tip end vertical portion 15c, the tip end horizontal portion 15a and the tip end second horizontal portion 15b.

Next, there will be described an embodiment in which the rubber-based hot-melt adhesive (hot butyl) M is applied to the four edge portions of the work W to be coated, which is a rectangular flat-plate-shaped photovoltaic cell panel.

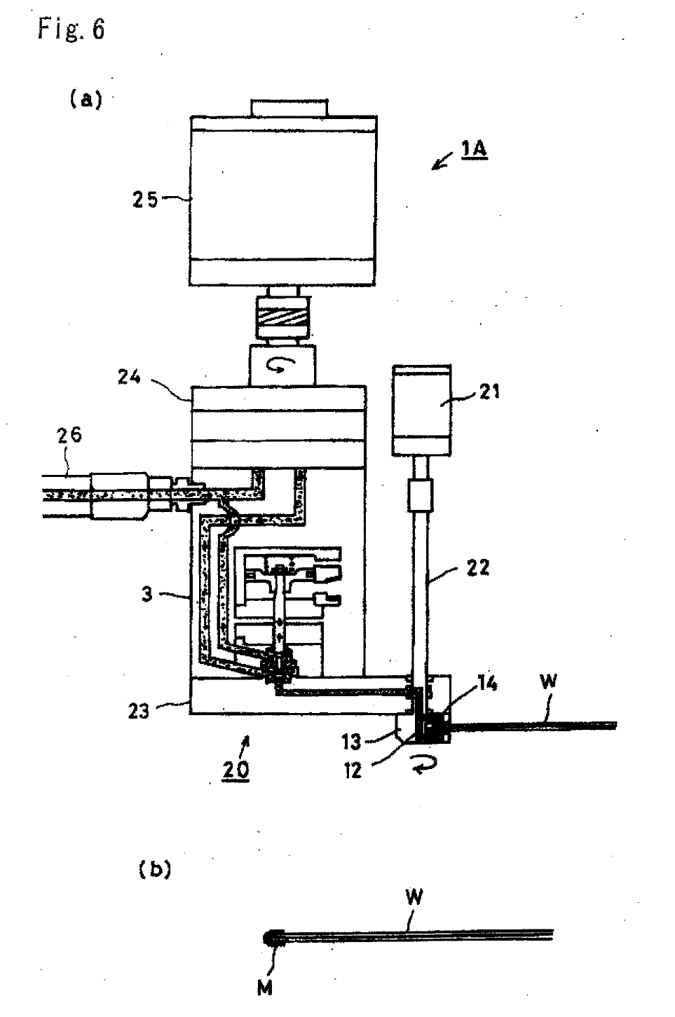

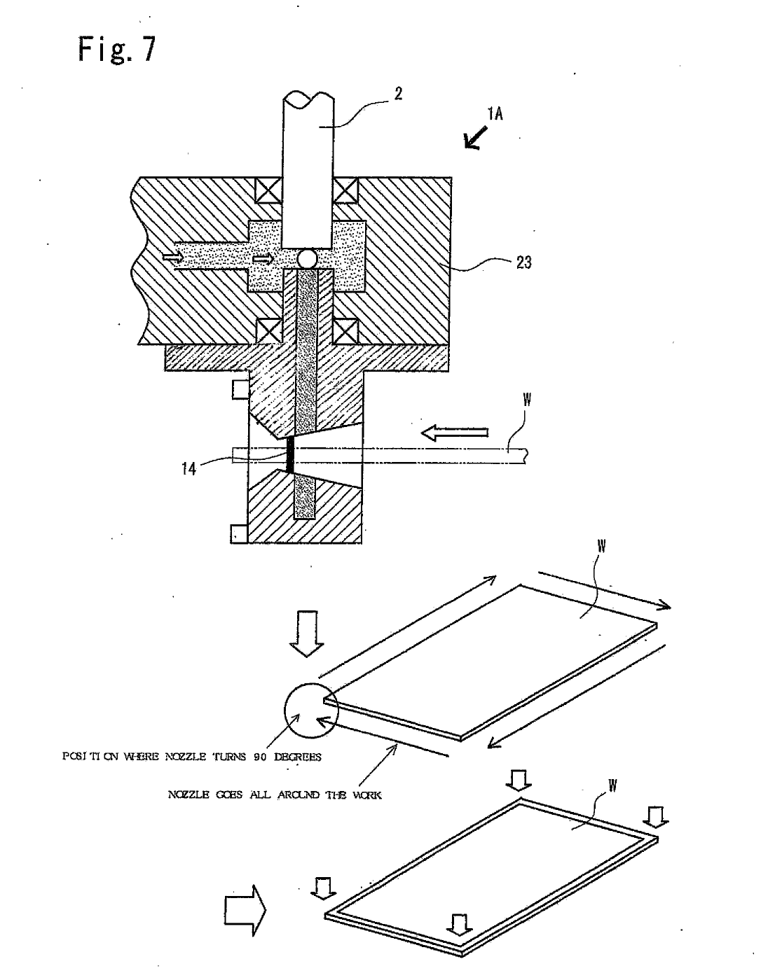

An embodiment shown in FIGS. 6(a) and 6(b), and FIG. 7 is an embodiment practiced by change in direction of the single applying head 13 (that is, an embodiment of the invention in Claim 14).

Referring to FIG. 6(a), an applying unit 1A is provided with the gun unit 3 of a main body block 20 and a support table 23 having an axis support for rotatably supporting the applying head 13 so as to rotatably support a rotation axis 22 integral with the applying head 13, and the applying unit 1 A is further equipped with a servo motor 21 on the upper side of the rotation axis 22.

In FIGS. 6(a) and 6(b), 24 denotes a gear pump, 25 denotes a servo motor and a decelerator, and 26 denotes a supply hose.

FIG. 6(b) shows an application state by the applying unit 1A, in which the sealing coating agent M surrounds the edge surface, upper surface and lower surface of the edge portion of the work W to be coated.

Referring to FIG. 7, by turning the applying head 90 degrees at each corner of the work W to be coated (rectangular photovoltaic cell panel), it is possible to perform a continuous unicursal applying operation on the whole circumferential surface of the work W to be coated.

Next, an embodiment of an applying unit 1B equipped with four applying heads 31A, 31B, 31C and 31D (that is, an embodiment of the invention in Claim 15) will be described.

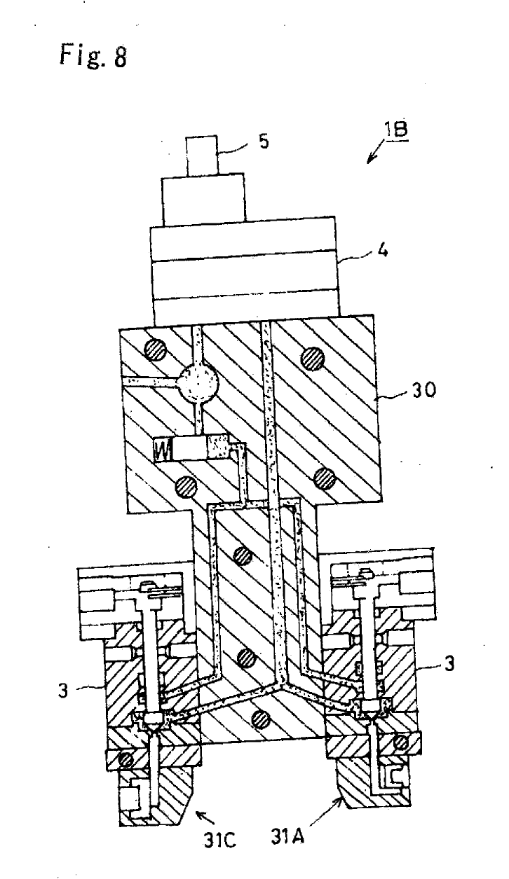

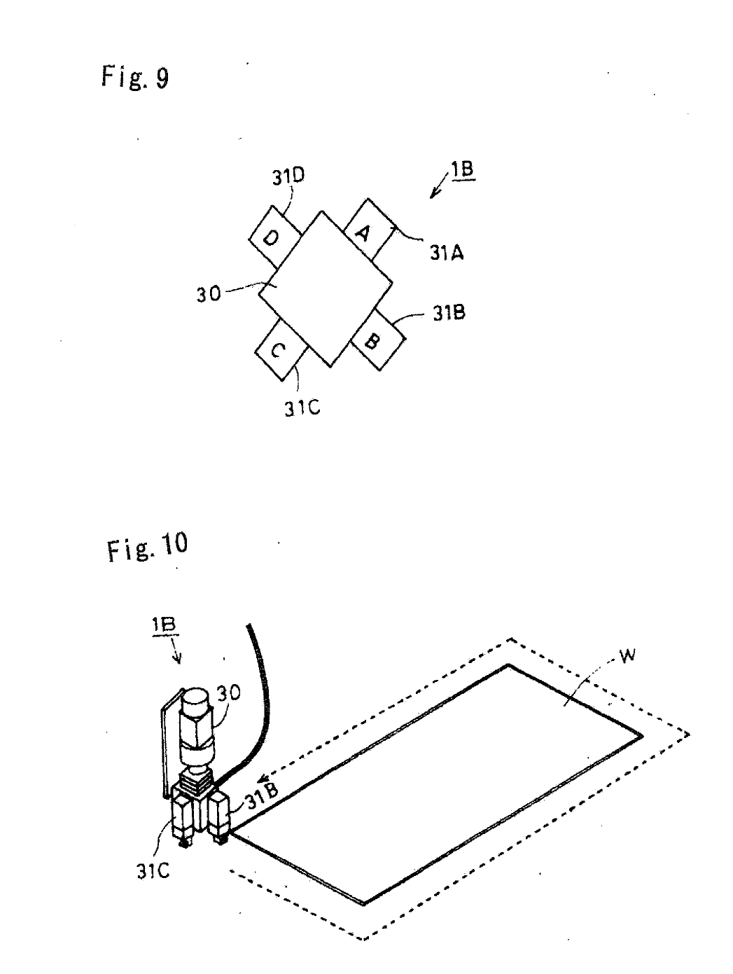

Referring to FIGS. 8 and 9, the applying unit 1B is equipped on the lower side of a gun unit main body 30 with the four applying heads 31A, 31B, 31C and 31D projecting to the lateral sides.

The four applying heads 31A, 31B, 31C and 31D share a supply circuit and a return circuit for the sealing coating agent M but have independent valve mechanisms, and thus any one of the applying heads is selected and operated.

The tip end vertical portions 15c of the coating agent discharge ports 14 of the four applying heads 31A, 31B, 31C and 31D are shifted 90 degrees from one another and thus face in different directions of front, back, left and right directions.

Referring to FIG. 10, by sequentially switching the operating applying head from 31A to 31B, from 31B to 31C, and from 31C to 31D at the respective corners of the work W to be coated (rectangular photovoltaic cell panel), it is possible to perform a continuous applying operation on the whole circumferential surface of the work W to be coated.

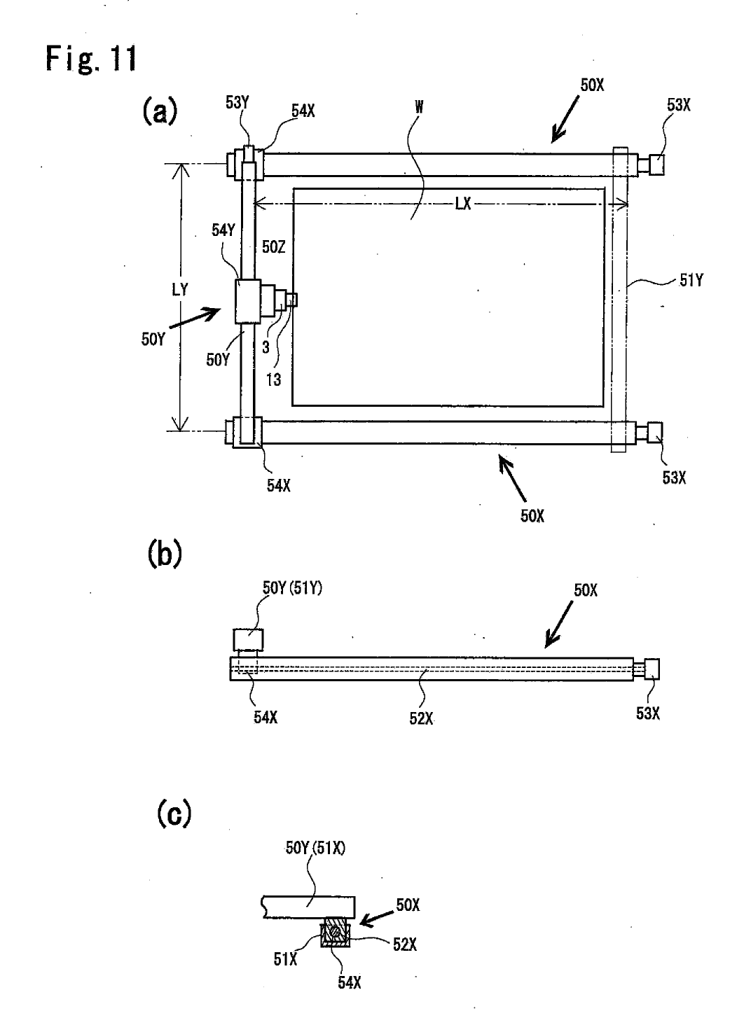

FIGS. 11(a) to 11(c) show a horizontal moving mechanism of a gun unit 3.

A pair of X-direction driving mechanisms 50X are arranged on both the lateral sides of the work W to be coated (rectangular photovoltaic cell panel), and a Y-direction driving mechanism 50Y is provided in a state where both the edges of the work are mounted on the pair of X-direction driving mechanisms 50X.

Each of the X-direction driving mechanisms 50X is equipped with a rotation axis 52X in an X-direction driving case 51X formed in a quadrangular prism shape, and is equipped with a servo motor 53X at the end portion of the rotation axis 52X. A moving block 54X threaded onto the rotation axis is guided by the X-direction driving case 51X by rotation of the servo motor 53X so as to be movable in the X-axis direction. A part of the moving block 54X is exposed from the upper surface of the X-direction driving case 51X.

The Y-direction driving mechanism SOY is equipped with a rotation axis 52Y in a Y-direction driving case 51Y formed in a quadrangular prism shape, and is equipped with a servo motor 53Y at the end portion of the rotation axis 52Y. A moving block 54Y threaded onto the rotation axis 52Y is guided by the Y-direction driving case 51Y by rotation of the servo motor 53Y so as to be movable in the Y-axis direction. A part of the moving block 54Y is exposed from the upper surface of the Y-direction driving case 51Y.

Both the end portions of the Y-direction driving case 51Y of the Y-direction driving mechanism 50Y are fixed to the respective moving blocks 54X of the pair of right and left X-direction driving mechanisms 50X.

FIGS. 12(a) and 12(b) show a vertical moving mechanism of the gun unit 1.

The gun unit 1 infixed to a moving block 54Z of a Z-direction driving mechanism 50Z fixed to the moving block 54Y of the Y-direction driving mechanism 50Y.

The Z-direction driving mechanism 50Z is equipped with a rotation axis 52Z in a Z-direction driving case 51 Z formed in a quadrangular prism shape, and is equipped with a servo motor 53Z at the end portion of the rotation axis 52Z. The gun unit 1 is fixed to a moving block 54Z that moves vertically by rotation of the rotation axis 52Z, and the moving block 54Z is guided and supported by a guide recess of the Z-direction driving case 51Z and is driven vertically by rotation of the servo motor 53Z.

FIGS. 13(a) and 13(b) describe change in the distance d1.

Referring to FIG. 13(a), in a case where applying conditions under which a thickness t of the work W to be coated is 5 mm, and under which the distance d1 is 0.5 mm are changed to those under which a distance d1′ is 1.0 mm, the servo motor 53Z of the Z-direction driving mechanism 50Z is rotated so that the moving block 54Z may be raised by da=0.5 mm to bring a state shown in FIG. 13(b).

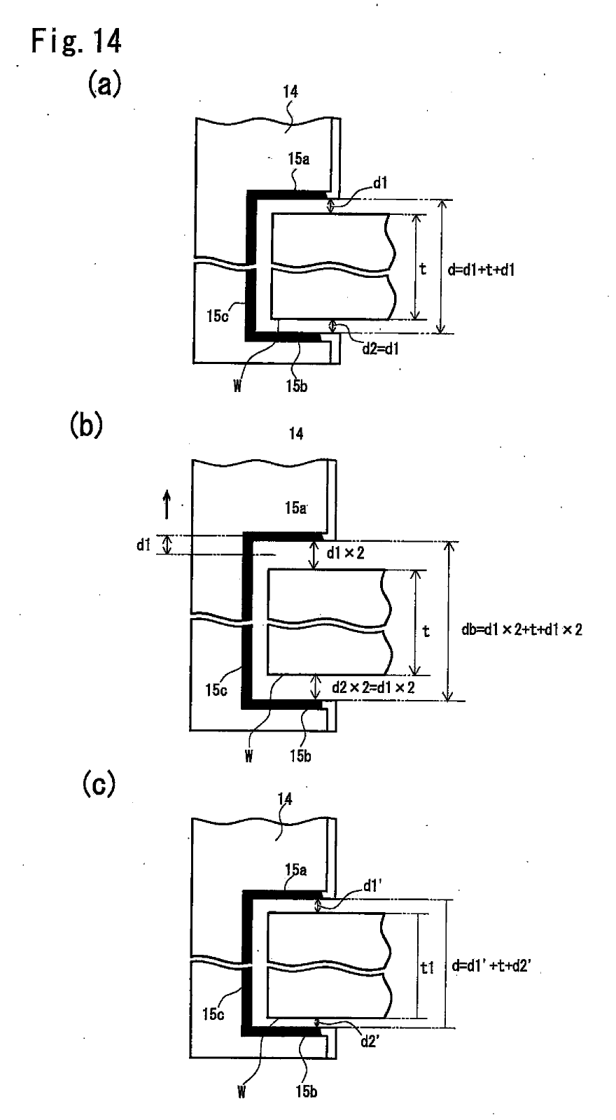

FIGS. 14(a) to 14(c) describe change in the distances d1 and d2.

Referring to FIG. 14(a), in a case where applying conditions under which the thickness t of the work W to be coated is 5 mm, and under which the distances d1 and d2 are respectively 0.5 mm [d1=d2] are changed to those under which distances and d1′ and d2′ are respectively 1.0 mm [d1=d2] (the distances d1 and d2 are doubled), the applying nozzle 13 whose opening vertical width D is 6 mm is replaced with the applying nozzle 13 whose opening vertical width Da is 7 mm, which is then attached to the nozzle unit 1, and the servo motor 53Z of the Z-direction driving mechanism 50Z is rotated so that the moving block 54Z may be raised by db=0.5 mm to bring a state shown in FIG. 14(b).

In a case where applying conditions under which the thickness t of the work W to be coated is 5 mm, and under which the distances d1 and d2 are respectively 0.6 mm [d1=d2] are changed to those under which distances d1″ and d2″ are respectively 0.8 mm and 0.4 mm [d1 is twice as large as d2] (the distance d1 is increased while the distance d2 is decreased), the applying nozzle 13 whose opening vertical width D is 6.2 mm does not need to be replaced (the opening vertical width D of the applying nozzle 13 being 6.2 mm remains the same), but the servo motor 53Z of the Z-direction driving mechanism 50Z is rotated so that the moving block 54Z may be raised by dc=0.3 mm to bring a state shown in FIG. 14(c).

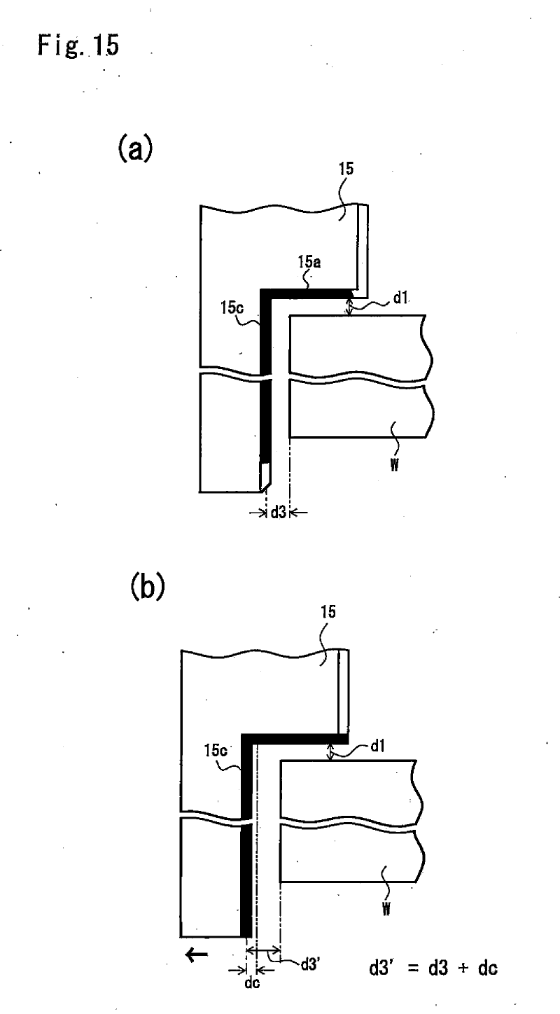

FIGS. 15(a) and 15(b) describe change in the distance d3.

Referring to FIG. 15(a), in a case where applying conditions under which the distance d3 is 0.5 mm are changed to those under which a distance d3′ is 1.0 mm, the servo motor 53X of the X-direction driving mechanism 50X is rotated so that the moving block 54X may be moved in the left direction by dx=0.5 mm to bring a state shown in FIG. 15(b). Meanwhile, depending on the position of the nozzle unit 1, different movement operations such as movement of the moving block 54Y of the Y-direction driving mechanism, movement in the right direction of the moving block 54X of the X-direction driving mechanism, and the like are performed.

In practicing the invention according to Claim 7, applying a rubber-based hot-melt adhesive (hot butyl) as a sealing coating agent and providing the aforementioned gun unit with heating means allow the rubber-based hot-melt adhesive (hot butyl) supplied to the applying nozzle in a molten state discharged in a liquid state from the tip end of the coating agent discharge port.

In a state where the rubber-based hot-melt adhesive (hot butyl) M has been applied on the coating surface of the work to be coated, the rubber-based hot-melt adhesive (hot butyl) M is cooled and is changed into a solid state.

Thus, the rubber-based hot-melt adhesive (hot butyl) applied to the work to be coated is changed from a liquid state to a solid state. This enables the subsequent operations to be performed continuously and also makes the subsequent operations easy.

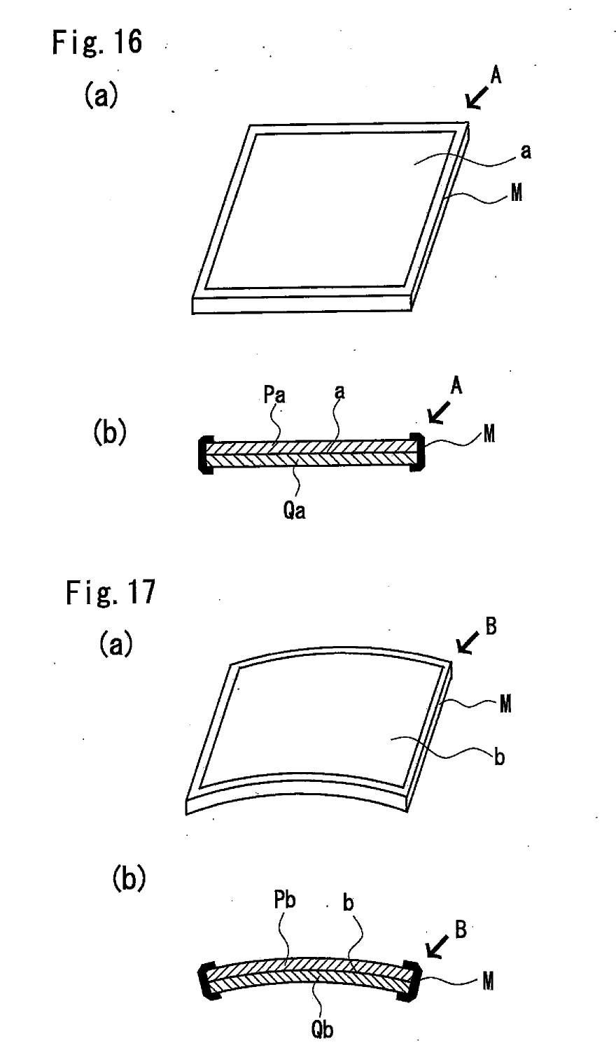

As for double-layered products A and B to which the present invention has been applied, the double-layered product A is formed in a flat plate shape in FIGS. 16(a) and 16(b) while the double-layered product B is formed in a curved plate shape (arc cross-section) in FIGS. 17(a) and 17(b), and a light receiving element plate a and a light emitting element plate b of a photovoltaic cell panel and an electronic panel are respectively formed in a flat plate shape and a curved plate shape. Moreover, upper plates Pa, Pb and lower plates Qa, Qb are respectively formed in a flat plate shape and a curved plate shape. The upper plates Pa, Pb and the lower plates Qa, Qb are formed in fixed shapes as rigid plastic products, glass products or the like. However, in a case where the light receiving element plates a and b of the photovoltaic cell panel and the electronic panel are made deformable as a flexible organic EL plate, the upper plates Pa, Pb and the lower plates Qa, Qb are made of a flexible material such as a flexible plastic sheet. In such a case, by using the rubber-based hot-melt adhesive (hot butyl) M as the sealing coating agent, a moisture entry prevention effect of the present invention can be sufficiently achieved. Making the photovoltaic cell panel and the electronic panel flexible is effective in installing the panels on a curved surface of a building by attaching the panels on an exterior wall surface.

### INDUSTRIAL APPLICABILITY

The present invention promotes manufacture and utilization of a double-layered product such as a photovoltaic cell panel for photovoltaic generation or an electronic panel (a liquid crystal plate, an organic EL plate) for TV image display or PR image display (an electronic advertising display plate) and contributes to development of the industry of this kind.

1. A method for sealing an edge portion of a double-layered product, the method including the steps of discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port,
wherein a hot-melt adhesive is used as the sealing coating agent,
a tip end of the coating agent discharge port is arranged to face at least two surfaces (an edge surface and an upper surface) of an edge portion of a double-layered product serving as the work to be coated,
and a thickness of an applied coating agent M at a part parallel to an upper surface of a work W to be coated is changeably set by setting of a distance between the tip end of the coating agent discharge port and the upper surface of the work to be coated.

2. A method for sealing an edge portion of a double-layered product, the method including the steps of: discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port,
wherein a hot-melt adhesive is used as the sealing coating agent,
the coating agent discharge port is arranged to face at least three surfaces (an edge surface, an upper surface and a lower surface) out of circumferential surfaces at an edge portion of a double-layered product so as to discharge the sealing coating agent to the three surfaces (the edge surface, the upper surface and the lower surface) at the edge portion of the double-layered product,
a thickness of an applied coating agent M at a part parallel to an upper surface of a work W to be coated is changeable by setting of a distance between a tip end of the coating agent discharge port and the upper surface of the work to be coated,
and a thickness of the applied coating agent M at a part parallel to a lower surface of the work W to be coated is changeable by setting of a distance between the tip end of the coating agent discharge port and the lower surface of the work to be coated.

3. A method for sealing an edge portion of a double-layered product, the method including the steps of discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port,
wherein a hot-melt adhesive is used as the sealing coating agent,
the coating agent discharge port is arranged to face at least three surfaces (an edge surface, an upper surface and a lower surface) out of circumferential surfaces at an edge portion of a double-layered product so as to discharge the sealing coating agent to the three surfaces (the edge surface, the upper surface and the lower surface) at the edge portion of the double-layered product, a thickness of an applied coating agent M at a part parallel to an upper surface of a work W to be coated is changeable by setting of a distance between a tip end of the coating agent discharge port and the upper surface of the work to be coated,
a thickness of the applied coating agent M at a part parallel to a lower surface of the work W to be coated is changeable by setting of a distance between the tip end of the coating agent discharge port and the lower surface of the work to be coated,
and a thickness of the applied coating agent M at an edge of the edge portion of the work W to be coated is changeable by setting of a distance between the tip end of the coating agent discharge port and an edge of the work to be coated.

4. A method for sealing an edge portion of a double-layered product, the method including the steps of discharging a sealing coating agent supplied from an applying unit main body from a coating agent discharge port formed at an applying nozzle at a tip end portion of a gun unit; and applying the sealing coating agent to a coating surface of a work to be coated facing the coating agent discharge port,
wherein a hot-melt adhesive is used as the sealing coating agent, the coating agent discharge port is arranged to face at least three surfaces (an edge surface, an upper surface and a lower surface) out of circumferential surfaces at an edge portion of a double-layered product so as to discharge the sealing coating agent to the three surfaces (the edge surface, the upper surface and the lower surface) at the edge portion of the double-layered product,
a thickness of an applied coating agent M at a part parallel to an upper surface of a work W to be coated is changeable by setting of a distance between a tip end of the coating agent discharge port and the upper surface of the work to be coated,
a thickness of the applied coating agent Mat a part parallel to a lower surface of the work W to be coated is changeable by setting of a distance between the tip end of the coating agent discharge port and the lower surface of the work to be coated,
and the gun unit is made to be supported by gun unit driving means via a vertical positional adjusting mechanism so that the distance between the tip end of the coating agent discharge port and the upper surface of the work to be coated may be changeable by operation of the vertical positional adjusting mechanism to obtain a desired value for the thickness of the applied coating agent M.

5. A method for sealing an edge portion of a double-layered product, the method including the steps of discharging a sealing coating agent supplied from an applying unit main body from a coating agent discharge port formed at an applying nozzle at a tip end portion of a gun unit; and applying the sealing coating agent to a coating surface of a work to be coated facing the coating, agent discharge port,
wherein a hot-melt adhesive is used as the sealing coating agent, the coating agent discharge port is arranged to face at least three surfaces (an edge surface, an upper surface and a lower surface) at an edge portion of a double-layered product so as to discharge the sealing coating agent to the three surfaces (the edge surface, the upper surface and the lower surface) at the edge portion of the double-layered product,
the gun unit is made to be supported by gun unit driving means via a vertical positional adjusting mechanism so that a distance between a tip end of the coating agent discharge port and the upper surface of the work to be coated and a distance between the tip end of the coating agent discharge port and the lower surface of the work to be coated may be changeable by operation of the vertical positional adjusting mechanism to obtain a desired value for the thickness of the applied coating agent M.

6. In the method for sealing an edge portion of a double-layered product according to any one of claims 1-5,
a plurality of applying nozzles having different vertical distances of laterally-facing application spaces are provided
and selectively used to adjust a space against the work to be coated and obtain a desired value for the thickness of the applied coating agent M.

7. In the method for sealing an edge portion of a double-layered product according to any one of claims 1-5,
a rubber-based hot-melt adhesive is used as the hot-melt adhesive serving as the sealing coating agent,
and the gun unit with heating means is provided to so as to allow the rubber-based hot-melt adhesive (hot butyl) supplied to the applying nozzle in a molten state is discharged in a liquid state from the tip end of the coating agent discharge port, and in a state where the rubber-based hot-melt adhesive (hot butyl) M has been applied on the coating surface of the work to be coated,
the rubber-based hot-melt adhesive M is cooled and is changed into a solid state, thereby changing the rubber-based hot-melt adhesive (hot butyl) M applied to the work to be coated into a solid state.

8. In the method for sealing an edge portion of a double-layered product according to any one of claims 1-5,
wherein the double-layered product being the photovoltaic cell panel.

9. In the method for sealing an edge portion of a double-layered product according to any one of claims 1-5,
wherein the double-layered product being the electronic panel.

10. An apparatus for sealing an edge portion of a double-layered product, the apparatus for discharging a sealing coating agent supplied from an applying unit main body from a coating agent discharge port formed at an applying nozzle at a tip end portion of a gun unit, and applying the sealing coating agent to a coating surface of a work to be coated facing the coating agent discharge port,
wherein a tip end of the coating agent discharge port is formed in a slit shape facing a part of a vertical cross-sectional circumferential surface shape of the edge portion of the double-layered product serving as the work to be coated.

11. In the apparatus for sealing an edge portion of a double-layered product according to claim 10,
the top of a tip end portion of a gun unit being the L sharpie in the cross-section view of the applying nozzle.

12. In the apparatus for sealing an edge portion of a double-layered product according to claim 10,
the top of a tip end portion of a gun unit being the [symbol] sharpie in the cross-section view of the applying nozzle.

13. In the apparatus for sealing an edge portion of a double-layered product according to claim 10,
the top of a tip end portion of a gun unit being the sharpie having particle circle in the cross-section view of the applying nozzle.

14. An apparatus for sealing an edge portion of a double-layered product, the apparatus for discharging a sealing coating agent supplied from an applying unit main body from a coating agent discharge port formed at an applying nozzle at a tip end portion of a gun unit, and applying the sealing coating agent to a coating surface of a work to be coated facing the coating agent discharge port,
wherein a tip end of the coating agent discharge port is formed in a slit shape facing a part of a vertical cross-sectional circumferential surface shape of the edge portion of the double-layered product serving as the work to be coated,
and having a mechanism for rotating the applying nozzle to allow a direction of the slit-shaped coating agent discharge port changeable as viewed in a planar state.

15. An apparatus for sealing an edge portion of a double-layered product, the apparatus for discharging a sealing coating agent supplied from an applying unit main body from a coating agent discharge port formed at an applying nozzle at a tip end portion of a gun unit, and applying the sealing coating agent to a coating surface of a work to be coated facing the coating agent discharge port,
wherein a tip end of the coating agent discharge port is formed in a slit shape facing a part of a vertical cross-sectional circumferential surface shape of the edge portion of the double-layered product serving as the work to be coated,
the gun unit having a plurality of applying nozzles in which, the direction of the slit-shaped coating agent discharge port is different each other
and by selectively operating a plurality of applying nozzles and by changing a relative position of the gun unit to each edge of the edge portion of the double-layered product to allow a direction of the slit-shaped coating agent discharge port changeable as viewed in a planar state.

16. The apparatus for sealing an edge portion of a double-layered product according to any one of claims 11-15,
wherein the double-layered product being the photovoltaic cell panel.

17. The apparatus for sealing an edge portion of a double-layered product according to any one of claims 11-15,
wherein the double-layered product being the electronic panel.

18. An apparatus for sealing an edge portion of a double-layered product, the apparatus for discharging a sealing coating agent supplied from an applying unit main body from a coating agent discharge port formed at an applying nozzle at a tip end portion of a gun unit, and applying the sealing coating agent to a coating surface of a work to be coated facing the coating agent discharge port,
wherein a tip end of the coating agent discharge port is formed in a slit shape facing a part of a vertical cross-sectional circumferential surface shape of the edge portion of the double-layered product serving as the work to be coated,
the double-layered product is structured to sandwich a flexible light receiving element plate or a light emitting element plate between upper and lower plates made of flexible plastic sheets.
